(19) United States
(12) Patent Application Publication
(10) Pub. No.: US 2018/0090652 A1
(43) Pub. Date: Mar. 29, 2018

(54) OPTOELECTRONIC DEVICE ARRAY AND METHOD FOR PRODUCING A MULTIPLICITY OF OPTOELECTRONIC DEVICE ARRAYS

(71) Applicant: OSRAM Opto Semiconductors GmbH, Regensburg (DE)

(72) Inventors: Thomas SCHWARZ, Regensburg (DE); Frank SINGER, Regenstauf (DE)

(73) Assignee: OSRAM Opto Semiconductors GmbH, Regensburg (DE)

(21) Appl. No.: 15/568,785

(22) PCT Filed: Apr. 13, 2016
(86) PCT No.: PCT/EP2016/058110

§ 371 Date: Oct. 23, 2017

(30) Foreign Application Priority Data
Apr. 27, 2015 (DE) 102015106444.8

(51) Int. Cl. H01L 33/64; H01L 25/075; H01L 25/16; H01L 31/024; H01L 25/04; H01L 33/54; H01L 33/62; H01L 31/0203; H01L 31/02

(52) U.S. Cl. CPC H01L 33/641; H01L 25/0753; H01L 25/167; H01L 31/024; H01L 25/042; H01L 2933/0075; H01L 33/62; H01L 31/0203; H01L 31/02005; H01L 2933/0033; H01L 2933/005; H01L 33/54

(57) ABSTRACT

The invention relates to an optoelectronic component array (100) with a plurality of adjacent optoelectronic semiconductor components (60) and a covering body (81). According to the invention—each of the optoelectronic semiconductor components (60) has a ceramic support element (19) and a semiconductor chip (50) which is arranged on an upper face of the ceramic support element and which comprises a semiconductor element (54) designed to generate and/or receive radiation—the covering body (81) surrounds each of the ceramic support elements (19) of the optoelectronic semiconductor components in some regions at least in a lateral direction and connects adjacent ceramic support elements (19) together, and—the lower face of each of the ceramic support elements (19) is electrically insulated from the semiconductor chip (50).

This patent application claims the priority of German patent application DE 10 2015 106 444.8, the disclosure content of which is herewith incorporated by reference.

Efficient dissipation of heat is a key problem in optoelectronic devices. If optoelectronic semiconductor chips are arranged on heat dissipation elements having good thermal conductivity it is often desirable that the latter are of electrically insulating construction, so that they can be kept potential-free on their side remote from the semiconductor chips. This makes it possible to mount them directly on a metallic heat sink, especially without the use of an additional dielectric material. In that case the simultaneous mounting of a multiplicity of optoelectronic devices on a heat sink is also possible without the risk of a short circuit. The described problem is especially relevant in the case of semiconductor chips which are each contacted from their underside, that is to say from a side facing towards the heat dissipation element.

A solution to the problem known from the prior art lies in providing a device, especially a surface-mountable device, in which one or more semiconductor chips are arranged on a carrier made of an electrically insulating, ceramic material and which is then soldered onto a heat sink. In this case, however, the additional problem arises that, on account of the different thermal expansion coefficients of the ceramic material on the one hand and the solder material on the other hand, strong shear stresses arise in the solder which can result in damage to or failure of the solder, for example by tearing.

A problem is to define an optoelectronic device array in which an efficient dissipation of heat is provided by an electrically insulating element, while at the same time the risk of damage to the solder arranged therebelow is eliminated or reduced. A further objective is to define a method for producing a multiplicity of corresponding optoelectronic device arrays.

Those problems are solved inter alia by an optoelectronic device array and by a method for producing a multiplicity of optoelectronic device arrays according to the independent patent claims. Particular forms and advantageous arrangements are the subject matter of the dependent patent claims.

An optoelectronic device array having a multiplicity of optoelectronic semiconductor devices arranged one next to the other and an encapsulating body is defined.

Each of the optoelectronic semiconductor devices has a ceramic carrier body and a semiconductor chip which is arranged on an upper side of the ceramic carrier body and has a semiconductor body provided for generating and/or receiving radiation. By the use of a ceramic carrier body there is advantageously simultaneously achieved a good thermal conductivity and high electrical breakdown strength. Here and hereinbelow the upper side of the carrier body always denotes the side of the carrier body on which the semiconductor chip is arranged. Analogously, the underside of the carrier body denotes the side which is remote from the semiconductor chip. Furthermore, the upper side of the device array or of the encapsulating body analogously denotes a side of the respective elements that is arranged at the top when the device array is aligned so that the upper side of the carrier body is arranged at the top and the underside of the carrier body is accordingly arranged at the bottom.

Here and hereinbelow, the arrangement or application of a layer or an element “on” or “above” another layer or another element can mean that the one layer or the one element is arranged immediately in direct mechanical and/or electrical contact on the other layer or the other element. Furthermore, it can also mean that the one layer or the one element is arranged indirectly on or above the other layer or the other element. In that case further layers and/or elements can be arranged between the one layer and the other layer.

Preferably each of the semiconductor chips comprises a substrate on which there is arranged a semiconductor body and which is different from the ceramic carrier body. For example, the substrate is a growth substrate for the semiconductor layers of the semiconductor body. Alternatively, the substrate is different from a growth substrate for the semiconductor layers of the semiconductor body. In that case the substrate serves for mechanical stabilization of the semiconductor body, so that the growth substrate is not necessary for that purpose and can be removed. A semiconductor chip from which the growth substrate has been removed is also referred to as a thin-film semiconductor chip. For example, the substrate can contain silicon, germanium or a metal or can consist thereof. The semiconductor body especially has an active region provided for generating or for receiving radiation. The semiconductor body, especially the active region, contains, for example, a III-V compound semiconductor material.

According to at least one embodiment of the device array it is provided that the encapsulating body surrounds each of the ceramic carrier bodies of the optoelectronic semiconductor devices in a lateral direction at least in regions and connects neighboring ceramic carrier bodies to one another. Here and hereinbelow a lateral direction is understood as being a direction parallel to a main extension plane of the semiconductor bodies. Here and hereinbelow a vertical direction is analogously understood as being a direction perpendicular to a main extension plane of the semiconductor bodies.

Preferably the encapsulating body is at least in places formed on the ceramic carrier body. That is to say, the material of the encapsulating body—the encapsulating composition—is in contact with the carrier body. Especially preferably the encapsulating body at least in places encapsulates the carrier body interlockingly. The encapsulating body can be made of a material which is transmissive, for example translucent or transparent (clear), or reflective (for example white) for at least a portion of the electromagnetic radiation that is emitted or is to be received by the optoelectronic semiconductor chip during operation of the semiconductor device. In other embodiments, however, the material is absorbent, for example black. The ceramic carrier bodies are preferably over-cast or over-molded with the encapsulating composition of the encapsulating body. That is to say, the encapsulating body is preferably produced by means of a casting or molding process. The encapsulating body can at the same time be both an encapsulation of the semiconductor chip and a housing for the semiconductor device.

The use of an encapsulating body, especially an encapsulating body made of a resilient material, has the effect that shear stresses in a solder used for attaching the device array to a circuit board are reduced, while an efficient dissipation of heat by the ceramic carrier bodies is still possible.

In addition, there is advantageously provided a device array which has a multiplicity of emission surfaces (or detection surfaces) but can be mounted, for example on a circuit board, in a single process step. For that purpose the device array is preferably configured so as to surface-mountable. In addition, a spacing between neighboring semiconductor chips can be selected to be very small; for example, a spacing between edges of neighboring semiconductor chips can be less than 200 μm, preferably less than 100 μm, for example less than 50 μm. As a result of the very small surface area occupied by the device array, sparing use can be made of expensive ceramics.

Preferably an elasticity modulus of the material of the encapsulating body is selected so that, on the one hand, the above-mentioned shear stresses in a solder used for mounting the device array are sufficiently small, but, on the other hand, the material is hard enough to prevent, for example, a deformation of bond wires on the upper sides of the ceramic carrier bodies.

According to at least one embodiment of the device array it is provided that in each case an underside of the ceramic carrier body is electrically insulated from the semiconductor chip. As a result, the ceramic carrier body is able to act as heat dissipation element, but at the same time efficient electrical insulation is provided, so that the underside of the ceramic carrier body can be kept potential-free.

According to at least one embodiment of the device array it is provided that the ceramic carrier body consists of an electrically insulating material and is free of electrically conductive through-connections. The carrier body accordingly serves solely for efficient dissipation of heat, but not for the electrical supply of the semiconductor chips. For example, the carrier body can contain one of the following materials or can consist thereof: an oxide ceramics, such as especially aluminum oxide; a non-oxide ceramics such as, for example, a carbide (for example silicon carbide) or a nitride (for example silicon nitride or boron nitride), or some other ceramic material which preferably contains no metal and no organic compounds. For example, the thickness of the ceramic carrier body is between 50 μm and 500 μm, especially preferably between 100 μm and 300 μm.

According to at least one embodiment of the device array it is provided that neighboring optoelectronic semiconductor devices are in electrically conductive connection with one another in the region of the upper sides of the carrier bodies. Such an electrically conductive connection can have been made, for example, by the use of bond wires or planar connecting elements which are arranged on the upper sides of the carrier bodies. Preferably the neighboring optoelectronic semiconductor devices are free of electrically conductive connecting elements and are especially electrically insulated from one another in the region of the undersides of their carrier bodies.

According to at least one embodiment of the device array it is provided that the optoelectronic semiconductor devices are arranged in a row or in a plurality of parallel rows and the semiconductor devices arranged in one of the rows are connected to one another in series. For example, the device array can comprise only a single row of optoelectronic semiconductor devices. Such an array is extremely simple to produce, because it requires a segmentation of the ceramic carrier used for production in only one direction. In other embodiments the device array comprises a plurality of rows of semiconductor devices which are then arranged, for example, in a two-dimensional matrix.

According to at least one embodiment of the device array it is provided that the encapsulating body contains a silicone, an acrylate or an epoxide. For example, the encapsulating body is formed by a black material. For example, the encapsulating body can contain a black epoxide material (“black epoxy”) or can consist thereof. Such a material can be obtained especially economically by virtue of its widespread use in electronics and is distinguished by good workability. The encapsulating body can, however, also consist, for example, of a white material, for example a white epoxide. In addition, the material can contain fillers, for example of silicon dioxide. Preferably the material of the encapsulating body is electrically insulating.

According to at least one embodiment of the device array it is provided that each of the semiconductor chips has at least one electrical contact on a side facing towards the ceramic carrier body, that is to say especially facing towards the upper side of the ceramic carrier body. For example, each of the semiconductor chips can be contacted from opposite sides. Alternatively, each of the semiconductor chips can have an upper side contact and an underside contact, that is to say can be contacted from two sides.

According to at least one embodiment of the device array it is provided that side faces of each of the ceramic carrier bodies have anchoring structures. By virtue of the anchoring structures, the adhesion between the encapsulating body and the ceramic carrier bodies can be improved by allowing interlocking engagement. The anchoring structures can have been formed, for example, as a result of the ceramic carrier used for the production of the device array being severed from opposite sides using saw blades different widths.

According to at least one embodiment of the device array it is provided that in each case an upper edge of the encapsulating body extends as far as the ceramic carrier bodies. In addition, it is preferable for a lower edge of the encapsulating body to terminate flush with the undersides of the ceramic carrier bodies. In this embodiment, the encapsulating body has a smaller thickness than the ceramic carrier bodies. In other words, the encapsulating body encompasses only the ceramic carrier bodies, while a remaining portion of the semiconductor devices comprising the semiconductor chip remains free of encapsulating body material.

According to at least one embodiment of the device array it is provided that the encapsulating body surrounds each of the semiconductor chips laterally. For example, in the encapsulating body there can have been formed a multiplicity of cavities in which the semiconductor chips are arranged. In this embodiment the encapsulating body preferably has a greater thickness than the ceramic carrier bodies.

According to at least one embodiment of the device array it is provided that a first metallization is formed on the upper side of each of the ceramic carrier bodies and/or a second metallization is formed on the underside of each of the ceramic carrier bodies. Preferably the semiconductor chip is arranged on the first metallization, for example soldered or adhesively bonded thereto, there being an electrically conductive connection between a contact of the semiconductor chip facing towards the ceramic carrier body and the first metallization. Furthermore, it is preferable for a second contact of the same semiconductor chip to be in electrically conductive connection with the first metallization of a neighboring semiconductor chip. As a result, a simple series connection of neighboring semiconductor chips can be achieved. The second metallization serves preferably for the mounting of the device array, for example on a circuit board, and supports the formation of a solder.

According to at least one embodiment of the device array it is provided that the optoelectronic device array has at least two through-connection elements by means of which the semiconductor devices are contacted from an underside of the optoelectronic device array. Preferably the through-connection elements are spaced apart laterally from the other semiconductor devices and are arranged, for example, in opposite edge regions of the device array.

According to at least one embodiment of the device array it is provided that each of the optoelectronic semiconductor devices comprises a conversion element which is arranged, for example, on a side of the semiconductor chip remote from the ceramic carrier body. The conversion element is especially configured to convert primary radiation having a first wavelength (for example from the blue spectral region) generated in the semiconductor chips into secondary radiation having a longer wavelength different from the first wavelength (for example from the yellow spectral region). For example, the semiconductor device is provided for generating mixed light, especially mixed light appearing white to the human eye. For example, the conversion element has a thickness of between 20 μm and 150 μm, especially preferably between 40 μm and 100 μm.

A method for producing a plurality of optoelectronic device arrays according to any one of the preceding claims comprises the following steps:
a) providing a ceramic carrier;
b) severing the ceramic carrier along a multiplicity of mutually parallel dividing lines;
c) providing a plurality of semiconductor chips, each of the semiconductor chips having a semiconductor body provided for generating and/or receiving radiation;
d) attaching the plurality of semiconductor chips to the ceramic carrier;
e) forming an encapsulation at least in regions in which the ceramic carrier has been severed;
f) singulating into a plurality of optoelectronic device arrays, each device array having a multiplicity of optoelectronic semiconductor devices arranged one next to the other and a portion of the encapsulation as encapsulating body and each of the optoelectronic semiconductor devices comprising at least a portion of the ceramic carrier as carrier body.

The encapsulation can especially be produced by means of a casting process. The term casting process here includes all production processes in which a molding composition is introduced into a predetermined mold and, especially, subsequently hardened. In particular, the term casting process includes casting, injection-molding, transfer molding and compression molding. Preferably the encapsulation is formed by compression molding or by a film-assisted transfer molding process.

According to at least one embodiment of the method it is provided that in step b) the ceramic carrier is severed only along the multiplicity of mutually parallel dividing lines. That is to say, the ceramic carrier is segmented only in one direction, with the result that an especially simple production method is provided, because the ceramic carrier is able to retain its mechanical stability.

According to at least one embodiment of the method it is provided that in step b) the ceramic carrier is severed along a multiplicity of mutually parallel first dividing lines and a multiplicity of second dividing lines perpendicular thereto. This makes it possible to produce a device array in which a plurality of mutually parallel rows of semiconductor devices are provided. In that case, however, it is generally necessary to take additional measures in order to support the mechanical stability of the ceramic carrier during the production process, for example the use of an auxiliary carrier such as, for example, an adhesive film on which the ceramic carrier is arranged while it is being severed.

According to at least one embodiment of the method it is provided that before step b) a multiplicity of first metallizations are formed on an upper side of the ceramic carrier and in step d) each of the semiconductor chips is arranged on a respective one of the first metallizations and is electrically conductively connected thereto. Preferably in each case an electrically conductive connection is made between a contact of the semiconductor chip facing towards the ceramic carrier and the first metallization.

According to at least one embodiment of the method it is provided that before step b) a multiplicity of second metallizations are formed on an underside of the ceramic carrier. The second metallizations serve preferably for the mounting of the device array, for example on a circuit board, and support the formation of a solder.

The production method described above is especially suitable for producing the optoelectronic device array. Features mentioned in connection with the method can therefore be employed also in respect of the semiconductor device, or vice versa.

Further features, particular forms and advantageous arrangements will be apparent from the following description of exemplified embodiments in conjunction with the Figures.

In the Figures, elements that are identical or similar or have identical action are denoted by the same reference symbols.

The Figures and the relative sizes of the elements illustrated in the Figures to one another should not be regarded as to scale; rather, the size of individual elements and especially layer thicknesses may have been exaggerated in the drawings for the purpose of better clarity and/or better understanding

In the drawings:

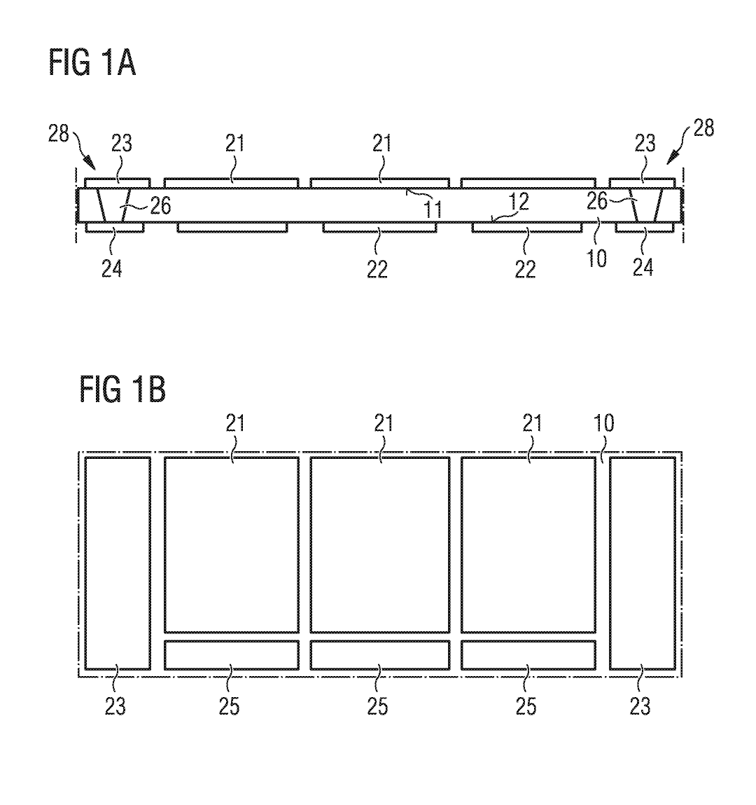

FIGS. 1 to 6 show an exemplified embodiment of a method for producing optoelectronic device arrays with reference to intermediate steps which are each shown in a diagrammatic sectional view and in plan view.

FIGS. 1 to 6 show an exemplified embodiment of a method for producing a plurality of optoelectronic device arrays. The Figures denoted by a) are in each case diagrammatic sectional views and the Figures denoted by b) are in each case the corresponding plan views.

As shown in FIG. 1, first of all a ceramic carrier 10, for example made of aluminum nitride, is provided, on the upper side 11 of which, in a later method step, there are arranged a plurality of semiconductor bodies. FIG. 1 and subsequent Figures show only a detail of the ceramic carrier 10; accordingly, the structures shown in the Figures need to be imagined as continuing in a two-dimensional grid. On the upper side 11 of the ceramic carrier 10 there are formed a multiplicity of first metallizations 21 arranged in a row and, respectively opposite on the underside 12 of the ceramic carrier 10, there are formed a multiplicity of second metallizations 22 arranged in a row. In the present case the first metallizations 21 have a greater width than the second metallizations 22.

In addition, in each of two regions which form opposite edge regions of the finished device array, a third metallization 23 is formed on the upper side 11 and a fourth metallization 24 is formed on the underside 12 of the ceramic carrier 10. The two third metallizations 23 are in electrically conductive connection with the respective two fourth metallizations 24 by way of a channel 26 filled with conductive material, which channel passes through the ceramic carrier 10, and form together therewith two through-connection elements 28. In addition, on the upper side 11 of the ceramic carrier 10 there are formed a multiplicity of fifth metallizations 25 arranged in a row, each of the fifth metallizations 25 being arranged next to a respective one of the first metallizations 21. The row forming the first metallizations 21 runs parallel to the row forming the fifth metallizations 25.

The metallizations can contain, for example, copper, nickel, palladium or gold or can consist of one of those metals.

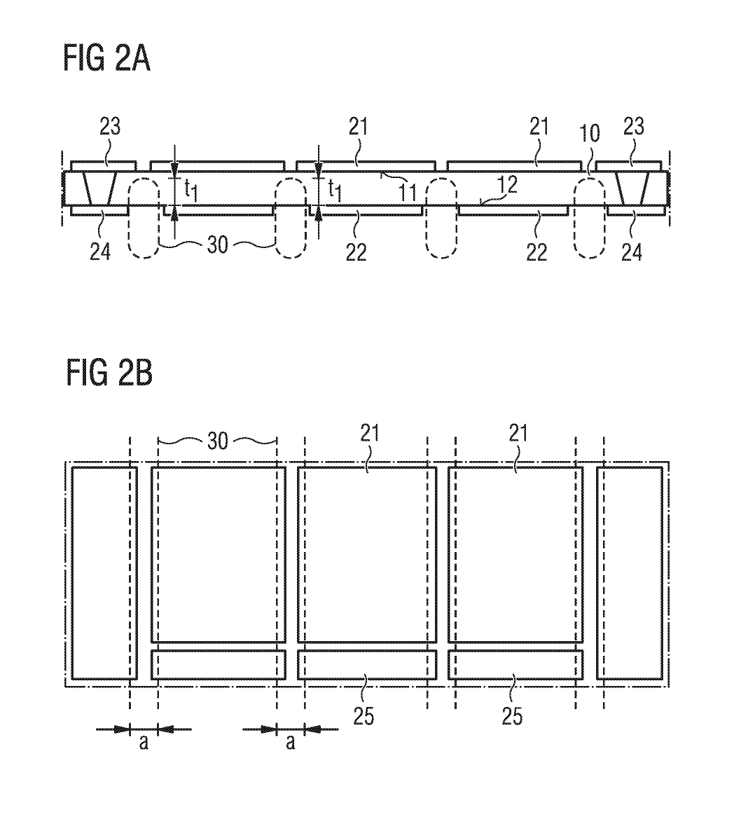

In the method step shown in FIG. 2, the ceramic carrier 10, from its underside 12, is partly sawn, for example corresponding to half its thickness, along mutually parallel dividing lines 30 and is thereby partly severed. The dividing lines 30 run between neighboring second metallizations 22 and between the opposite neighboring first metallizations 21. The dashed lines show the width a (for example 200 μm) and the depth t1 of the corresponding removal of material.

Preferably the ceramic carrier 10 is not severed over its entire extent, but is severed only in a central region of the total composite (of which the Figures show, as mentioned, only a detail). As a result, at the edge of the composite there remains a stable edge which ensures the required mechanical stability of the ceramic carrier 10. For example, a saw blade used for the sawing process can be inserted into the interior of the ceramic carrier, at a distance from an edge thereof, and raised before reaching the opposite edge, so that the edges are retained.

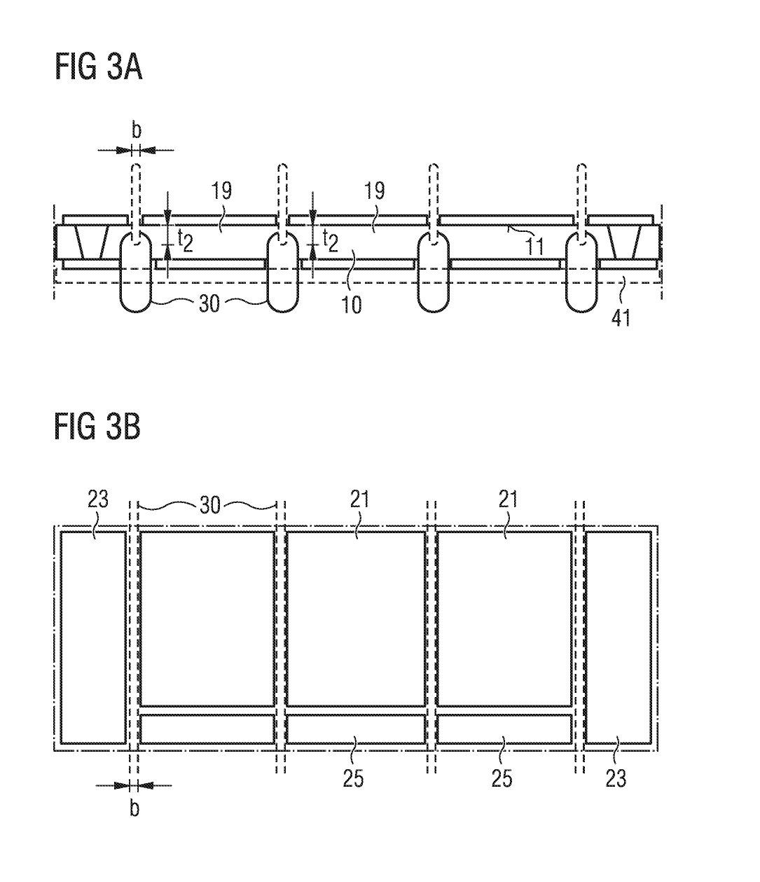

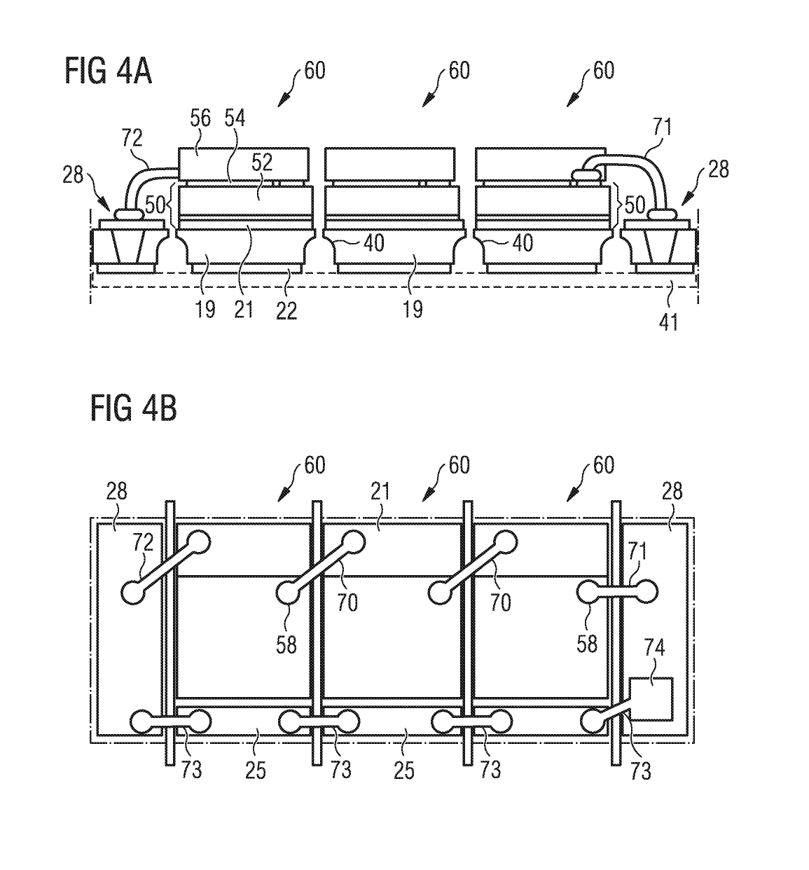

In the method step shown in FIG. 3, the ceramic carrier 10 is sawn, from its upper side 11, along the same dividing lines 30 using a thinner saw blade and is thereby fully severed, with the result that the ceramic carrier 10 is divided into a multiplicity of ceramic carrier bodies 19. The dashed lines again show the width b (for example 50 μm) and the depth t2 of the corresponding removal of material. To support the mechanical stability of the severed ceramic carrier 10 the latter can be arranged on an auxiliary carrier 40, for example adhesively bonded thereto. Severing the ceramic carrier 10 from opposite sides using saw blades of different widths has the result that side faces of each of the ceramic carrier bodies 19 in the finished device array have anchoring structures 40 (see FIG. 4). By virtue of the anchoring structures 40, the adhesion between the encapsulating body and the ceramic carrier bodies can be improved by allowing interlocking engagement at that location.

In an exemplified embodiment (not shown) the ceramic carrier 10 has already been segmented at the beginning of the process and has corresponding anchoring structures.

In the method step shown in FIG. 4, a multiplicity of semiconductor chips 50 are provided and attached to the ceramic carrier bodies 19. Each of the semiconductor chips 50 has a substrate 52 and a semiconductor body 54 arranged on the substrate 52. On the semiconductor body 54 there is also arranged a conversion element 56. Each of the semiconductor chips 50 has an underside contact (not shown) which is in electrically conductive connection with the first metallization 21 arranged therebelow. As a result, a multiplicity of optoelectronic semiconductor devices 60 are formed which each comprise a first and a second metallization 21, 22, a ceramic carrier body 19, a semiconductor chip 50 and a conversion element 56.

Furthermore, each of the semiconductor chips 50 has an upper side contact 58. In the case of neighboring pairs of optoelectronic semiconductor devices, in each case the first metallization 21 of one of the semiconductor devices is connected by a bond wire 70 to the upper side contact 58 of the other semiconductor device. As a result, the semiconductor devices 60 are connected to one another in series. The respective potentials of the semiconductor devices located at the outside are discharged by bond wires 71, 72 to the through-connection elements 28, which act as cathode and anode and between which a voltage can be applied from an underside of the finished device array. Finally, an electrically conductive connection is formed by means of bond wires 73 and the fifth metallizations 25, with the result that an ESD protection diode 74 can be connected between the two through-connection elements 28.

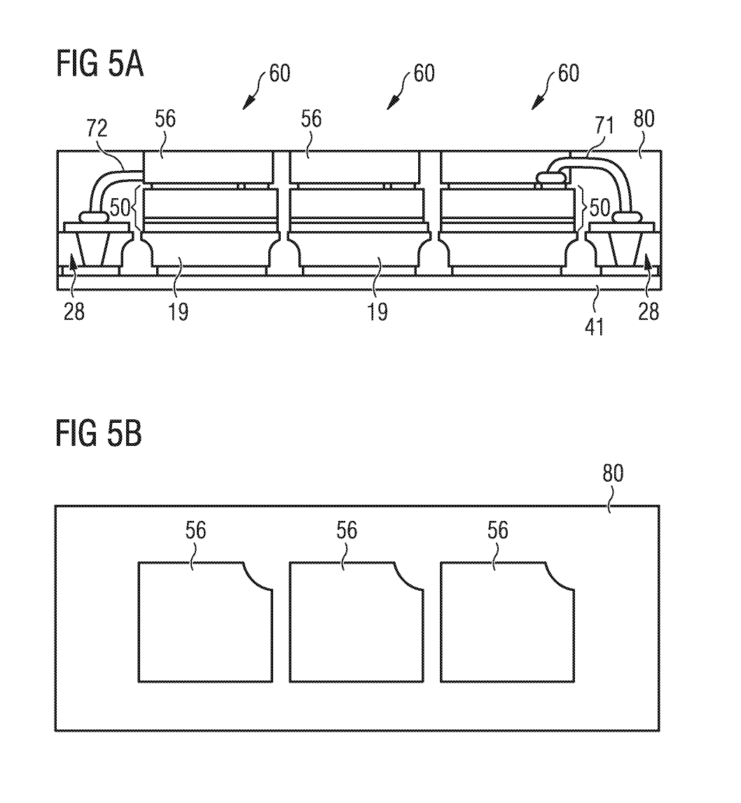

In the subsequent method step shown in FIG. 5, an encapsulation 80 is produced by compression molding or alternatively by filling using a dispensing process (“dam and fill”), which encapsulation, at least in regions, fills regions between the carrier bodies 19, the semiconductor chips 50 and the conversion element 56 of neighboring semiconductor devices 60.

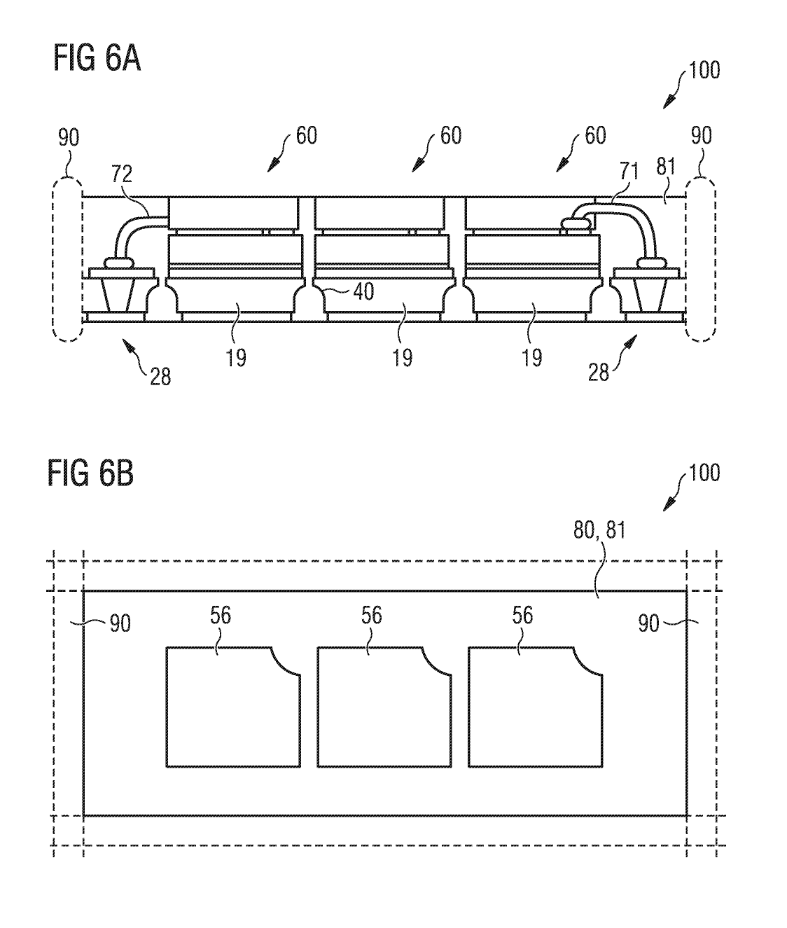

In the method step shown in FIG. 6, the total composite held together by the encapsulation 80 is singulated along singulation lines 90 into a multiplicity of optoelectronic device arrays 100. This can be effected, for example, mechanically, for example by means of sawing or stamping, chemically, for example by means of etching, and/or by means of coherent radiation, for example by laser ablation. FIG. 6 at the same time shows a finished device array 100.

Each finished device array 100 has a multiplicity of optoelectronic semiconductor devices 60 arranged one next to the other and a portion of the encapsulation 80 as encapsulating body 81 as well as two through-connection elements 28.

The description of the invention with reference to the exemplified embodiments does not limit the invention thereto; rather, the invention encompasses any novel feature and any combination of features, including in particular any combination of features in the patent claims, even if that feature or that combination is not itself explicitly defined in the patent claims or exemplified embodiments.

### LIST OF REFERENCE SYMBOLS:

10 carrier
11 upper side
12 underside
19 carrier body
21 first metallization
22 second metallization
23 third metallization
24 fourth metallization
25 fifth metallization
26 channel
28 through-connection elements
30 dividing lines
40 anchoring structures
41 auxiliary carrier
50 semiconductor chips
52 substrate
54 semiconductor body
56 conversion element
58 upper side contact
60 semiconductor devices
70 bond wire
71 bond wires
72 bond wires
73 bond wires
74 ESD protection diode
80 encapsulation
81 encapsulating body
90 singulation lines
100 device array
t1, t2 depth
a, b width

1. Optoelectronic device array having a multiplicity of optoelectronic semiconductor devices arranged one next to the other and an encapsulating body, wherein
each of the optoelectronic semiconductor devices has a ceramic carrier body and a semiconductor chip which is arranged on an upper side of the ceramic carrier body and has a semiconductor body provided for generating and/or receiving radiation,
the encapsulating body surrounds each of the ceramic carrier bodies of the optoelectronic semiconductor devices in a lateral direction at least in regions and connects neighboring ceramic carrier bodies to one another,
in each case an underside of the ceramic carrier body is electrically insulated from the semiconductor chip, and
the optoelectronic device array has at least two through-connection elements by means of which the semiconductor devices are contacted from an underside of the optoelectronic device array.

2. Optoelectronic device array according to claim 1, wherein the ceramic carrier body consists of an electrically insulating material and is free of electrically conductive through-connections.

3. Optoelectronic device array according to claim 1, wherein neighbouring optoelectronic semiconductor devices are in electrically conductive connection with one another in the region of the upper sides of the carrier bodies.

4. Optoelectronic device array according to claim 1, wherein the optoelectronic semiconductor devices are arranged in a row or in a plurality of parallel rows and the semiconductor devices arranged in one of the rows are connected to one another in series.

5. Optoelectronic device array according to claim 1, wherein the encapsulating body contains a silicone, an acrylate or an epoxide.

6. Optoelectronic device array according to claim 1, wherein each of the semiconductor chips has at least one electrical contact on a side facing towards the ceramic carrier body.

7. Optoelectronic device array according to claim 1, wherein side faces of each of the ceramic carrier bodies have anchoring structures.

8. Optoelectronic device array according to claim 1, wherein an upper edge of the encapsulating body in each case extends as far as the ceramic carrier bodies.

9. Optoelectronic device array according to claim 1, wherein the encapsulating body surrounds each of the semiconductor chips laterally.

10. Optoelectronic device array according to claim 1, wherein a first metallization is formed on the upper side of each of the ceramic carrier bodies or a second metallization is formed on the underside of each of the ceramic carrier bodies.

11. Method for producing a plurality of optoelectronic device arrays, having the steps:
a) providing a ceramic carrier;
b) severing the ceramic carrier along a multiplicity of mutually parallel dividing lines;
c) providing a plurality of semiconductor chips, each of the semiconductor chips having a semiconductor body provided for generating and/or receiving radiation;
d) attaching the plurality of semiconductor chips to the ceramic carrier;
e) forming an encapsulation at least in regions in which the ceramic carrier has been severed;
f) singulating into a plurality of optoelectronic device arrays, each device array having a multiplicity of optoelectronic semiconductor devices arranged one next to the other and a portion of the encapsulation as encapsulating body and each of the optoelectronic semiconductor devices comprising at least a portion of the ceramic carrier as carrier body.

12. Method according to claim 11, wherein in step b) the ceramic carrier is severed along a multiplicity of mutually parallel first dividing lines and a multiplicity of second dividing lines perpendicular thereto.

13. Method according to claim 11, wherein before step b) a multiplicity of first metallizations are formed on an upper side of the ceramic carrier and in step d) each of the semiconductor chips is arranged on a respective one of the first metallizations and is electrically conductively connected thereto.

14. Method according to claim 11, wherein before step b) a multiplicity of second metallizations are formed on an underside of the ceramic carrier.

15. Optoelectronic device array according to claim 1, wherein the encapsulating body encompasses only the ceramic carrier bodies, while a remaining portion of the semiconductor devices comprising the semiconductor chip remains free of encapsulating body material.

16. Optoelectronic device array having a multiplicity of optoelectronic semiconductor devices arranged one next to the other and an encapsulating body, wherein
each of the optoelectronic semiconductor devices has a ceramic carrier body and a semiconductor chip which is arranged on an upper side of the ceramic carrier body and has a semiconductor body provided for generating and/or receiving radiation,
the encapsulating body surrounds each of the ceramic carrier bodies of the optoelectronic semiconductor devices in a lateral direction at least in regions and connects neighboring ceramic carrier bodies to one another,
in each case an underside of the ceramic carrier body is electrically insulated from the semiconductor chip, and
the optoelectronic device array has at least two through-connection elements by means of which the semiconductor devices are contacted from an underside of the optoelectronic device array, wherein the encapsulating body encompasses only the ceramic carrier bodies, while a remaining portion of the semiconductor devices comprising the semiconductor chip remains free of encapsulating body material.
